(19) United States
(12) Patent Application Publication
(10) Pub. No.: US 2025/0176194 A1
(43) Pub. Date: May 29, 2025

(54) SEMICONDUCTOR DEVICES AND METHODS OF MANUFACTURING THE SAME

(71) Applicant: Samsung Electronics Co., Ltd., Suwon-si (KR)

(72) Inventors: INHO CHA, Suwon-si (KR); TAEJIN PARK, Suwon-si (KR); YOONA JANG, Suwon-si, Gyeonggi-do (KR); YONGKWAN KIM, Suwon-si (KR); HUIJUNG KIM, Suwon-si (KR); KISEOK LEE, Suwon-si (KR)

(21) Appl. No.: 18/732,746

(22) Filed: Jun. 4, 2024

(30) Foreign Application Priority Data
Nov. 27, 2023 (KR) 10-2023-0166492

(51) Int. Cl. H10B 80/00; H01L 23/00; H01L 25/00; H01L 25/065; H01L 25/18; H10B 12/00

(52) U.S. Cl. CPC H10B 80/00; H01L 24/08; H01L 24/80; H01L 25/0657; H01L 25/18; H01L 25/50; H10B 12/036; H10B 12/05; H10B 12/33; H01L 2224/08145; H01L 2224/80895; H01L 2224/80896; H01L 2924/1431; H01L 2924/1436

(57) ABSTRACT

A semiconductor device includes a cell array region, a bonding region and a central circuit region that are sequentially stacked. The cell array region may include a capacitor structure; a first gate structure on the capacitor structure; a channel on the third capacitor electrode, the channel having a semiconductor material with a first band gap energy greater than a second band gap energy of polysilicon; and a bit line. The capacitor structure may include a capacitor electrode structure having a first capacitor electrode on an upper surface of a first substrate, a mold on the first capacitor electrode, the mold comprising an opening therein, and a second capacitor electrode on the upper surface of the first capacitor electrode; a dielectric layer on a surface of the second capacitor electrode; and a third capacitor electrode on the dielectric layer.

### RELATED APPLICATIONS

This application claims priority under 35 U.S.C. § 119 to Korean Patent Application No. 10-2023-0166492 filed on Nov. 27, 2023 in the Korean Intellectual Property Office, the disclosure of which is hereby incorporated by reference in its entirety.

### TECHNICAL FIELD

Example embodiments relate to a semiconductor device and a method of manufacturing the same. More specifically, the present invention relates to a memory device including a vertical channel and a method of manufacturing the same.

### DESCRIPTION OF RELATED ART

Memory devices including vertical channel transistors are being developed to improve integration of semiconductor devices. In a method of manufacturing the semiconductor devices, a central circuit region (Core), a cell array region (Cell) and a wiring region (Back End Of Line, BEOL) may be sequentially stacked on a substrate. In this case, there are restrictions on the arrangement of wiring structures that connect the cell array region and the peripheral circuit region, or the central circuit region and the peripheral circuit region, and ultimately, mismatch due to difference between signals reaching the cell array region may occur.

### SUMMARY OF THE INVENTION

Example embodiments provide a semiconductor device having improved characteristics.

According to example embodiments, there is provided a semiconductor device. The semiconductor device may include a cell array region, a bonding region and a central circuit region that are sequentially stacked, and a peripheral circuit region surrounding the cell array region. The cell array region may include a capacitor structure; a first gate structure on the capacitor structure; a channel on the third capacitor electrode, the channel having a semiconductor material with a first band gap energy greater than a second band gap energy of polysilicon; and a bit line on the first gate structure and the channel, wherein the central circuit region includes a transistor on a second substrate, the transistor including a second gate structure and a source/drain region, wherein the bonding region includes a bonding structure that bonds the cell array region and the central circuit region to each other, and wherein the peripheral circuit region includes a peripheral circuit pattern that is configured to apply electrical signals to the cell array region. The capacitor structure may include a capacitor electrode structure having a first capacitor electrode on an upper surface of a first substrate, a mold on the first capacitor electrode, the mold having an opening therein, and a second capacitor electrode on the upper surface of the first capacitor electrode and a surface of the mold; a dielectric layer on a surface of the second capacitor electrode; and a third capacitor electrode on the dielectric layer in the opening of the mold.

According to example embodiments, there is provided a method of manufacturing a semiconductor device. The method of manufacturing a semiconductor device may include forming a cell array region and a central circuit region on a first substrate and a second substrate, respectively, the cell array region including a capacitor structure, a first gate structure, a channel and a bit line sequentially stacked on the first substrate, and the central circuit region including a transistor having a second gate structure and a source/drain region; bonding the cell array region and the central circuit region to each other. The forming the cell array region may include forming a first capacitor electrode on the first substrate; forming a first mold on the first capacitor electrode, the first mold having a first opening that exposes an upper surface of the first capacitor electrode; forming a second capacitor electrode on the upper surface of the first capacitor electrode and a surface of the first mold; forming a dielectric layer on the second capacitor electrode; forming a third capacitor electrode filling a remaining portion of the first opening to form the capacitor structure including the first capacitor electrode, the first mold, the second capacitor electrode, the dielectric layer and the third capacitor electrode; forming the first gate structure on the capacitor structure; forming the channel on the third capacitor electrode by a deposition process; and forming the bit line on the first gate structure and the channel.

According to example embodiments, there is provided a method of manufacturing a semiconductor device. The method of manufacturing a semiconductor device may include forming a cell array region and a central circuit region on a first substrate and a second substrate, respectively, the cell array region including a capacitor structure, a first gate structure, a channel and a bit line sequentially stacked on the first substrate, and the central circuit region including a transistor having a second gate structure and a source/drain region; bonding the cell array region and the central circuit region to each other. The forming the cell array region may include forming a first mold on the first substrate, the first mold having a first opening; forming a first capacitor electrode on a bottom and a sidewall of the first opening; forming a dielectric layer on a surface of the first capacitor electrode and a surface of the first mold; forming a second capacitor electrode filling a remaining portion of the first opening, where the capacitor structure includes the first mold, the first capacitor electrode, the dielectric layer and the second capacitor electrode; turning over the first substrate and removing the first substrate to expose the capacitor structure; forming the first gate structure on the capacitor structure; forming the channel on the first capacitor electrode by a deposition process; and forming the bit line on the first gate structure and the channel.

In a method of manufacturing a semiconductor device including vertical channel transistors, the cell array region and the central circuit region may be formed by separate processes, and then bonded together. In this case, components of the wiring structure may be placed relatively freely, and thus, mismatch between signals reaching the memory cells may be reduced.

A semiconductor device, according to some embodiments, may include a cell array region. The semiconductor device may include a central circuit region that is on top of the cell array region. Moreover, the semiconductor device may include a bonding region that is between the cell array region and the central circuit region. The cell array region may include a capacitor structure, a first gate structure on the capacitor structure, a channel on the first gate structure, and a bit line on the first gate structure and the channel. The central circuit region may include a transistor, which may include a second gate structure and a source/drain region. The bonding region may bond the cell array region and the central circuit region to each other.

A semiconductor device, according to some embodiments, may include a cell array region. The semiconductor device may include a central circuit region that is on top of the cell array region. The central circuit region may include a transistor. The semiconductor device may include a BEOL region on the central circuit region. The BEOL region may include a contact plug that extends into the central circuit region. Moreover, the semiconductor device may include a bonding region that is between the cell array region and the central circuit region. The cell array region may include a capacitor structure, a first gate structure on the capacitor structure, a channel on the first gate structure, and a bit line on the first gate structure and the channel. The central circuit region may include a transistor, which may include a second gate structure and a source/drain region. The bonding region may bond the cell array region and the central circuit region to each other.

### BRIEF DESCRIPTION OF THE DRAWINGS

FIG. 1 is a cross-sectional view illustrating a semiconductor device in accordance with example embodiments.

FIGS. 2 to 25 are plan views and cross-sectional views illustrating a method of manufacturing a semiconductor device according to example embodiments. FIGS. 2, 4, 6, 8, 10, 12, 14, 16, 18, 20, and 22 are plan views, and FIGS. 3, 5, 7, 9, 11, 13, 15, 17, 19, 21, and 23-25 are cross-sectional views.

FIGS. 26 to 28 are cross-sectional views illustrating semiconductor devices according to example embodiments.

FIG. 29 is a cross-sectional view illustrating a semiconductor device in accordance with example embodiments.

FIGS. 30 to 39 are plan views and cross-sectional views illustrating a method of manufacturing a semiconductor device according to example embodiments. FIGS. 30, 32, 34, 36 and 38 are plan views, and FIGS. 31, 33, 35, 37, and 39 are cross-sectional views.

### DETAILED DESCRIPTION

Hereinafter, two directions among horizontal directions that are substantially parallel to an upper surface of each of first to third substrates 10, 20 and 30, which may be substantially orthogonal to each other, may be referred as first and second directions D1 and D2, respectively. Additionally, a direction substantially perpendicular to the upper surface of each of the first to third substrates 10, 20 and 30 may be referred to as a third direction D3.

Each of the first to third directions D1, D2 and D3 may represent not only a direction shown in the drawing, but also a reverse direction to the direction.

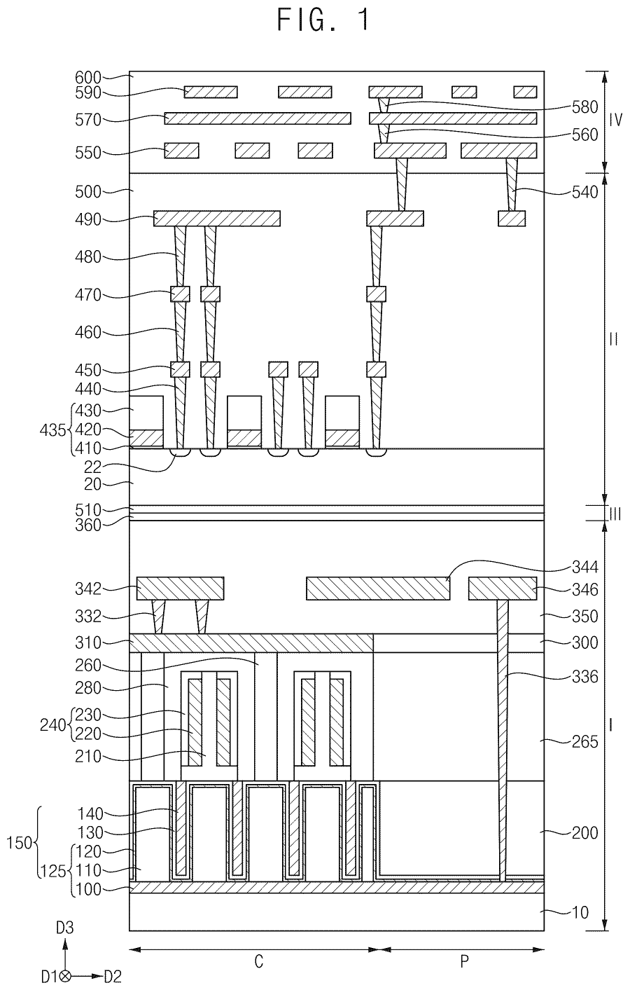

FIG. 1 is a cross-sectional view illustrating a semiconductor device in accordance with example embodiments.

Referring to FIG. 1, the semiconductor device may include a cell array region I, a bonding region III, a central circuit region II and wiring region IV.

The cell array region I in/on which memory cells are formed, may include a first capacitor structure 150, a first gate structure 240, a channel 280, second to fourth molds 210, 260 and 265, a bit line 310, first and third contact plugs 332 and 336, a second contact plug, first to third wirings 342, 344 and 346 and first to third insulating interlayers 200, 300 and 350 on a first substrate 10.

A peripheral circuit region, in/on which peripheral circuit patterns that apply signals to the memory cells are formed, may be disposed around (e.g., may surround) the cell array region I. The peripheral circuit patterns can be configured to apply electrical signals to the cell array region I. However, only the cell array region I is illustrated. For simplicity of illustration, the peripheral circuit region is omitted from view in FIG. 1.

The first substrate 10 may include a semiconductor material, e.g., silicon, germanium, silicon-germanium, etc., or a group III-V compound semiconductor, e.g., gallium phosphide (GaP), gallium arsenide (GaAs), gallium antimonide (GaSb), etc. In example embodiments, the first substrate 10 may be a silicon-on-insulator (SOI) substrate or a germanium-on-insulator (GOI) substrate.

In example embodiments, the first substrate 10 may include a central portion C where the first capacitor structure 150, the first gate structure 240, the channel 280 and the bit line 310 are formed, and a peripheral portion P excluding the central portion C.

The first capacitor structure 150 may include a capacitor electrode structure 125, a first dielectric layer 130 and a third capacitor electrode 140 sequentially stacked in the third direction D3 on the first substrate 10.

The capacitor electrode structure 125 may include a first capacitor electrode 100, a first mold 110 and a second capacitor electrode 120 sequentially stacked in the third direction D3. Accordingly, the first mold 110 may be between the first capacitor electrode 100 and the second capacitor electrode 120, with the second capacitor electrode 120 being on top of the first mold 110.

The first capacitor electrode 100 may be on (e.g., may cover) an upper surface of the first substrate 10.

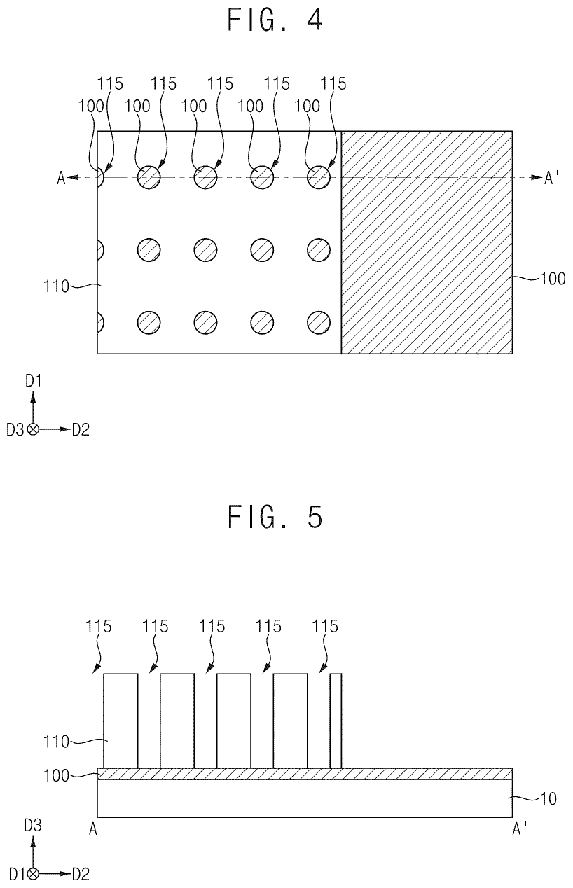

The first mold 110 may be disposed on a portion of the first capacitor electrode 100 on the central portion C of the first substrate 10. Referring to FIGS. 4 to 11 together with FIG. 1, the first mold 110 may include a first opening 115 exposing an upper surface of the first capacitor electrode 100. In a plan view, the first opening 115 may have a shape of a circle, but the present invention is not limited thereto. That is, in a plan view, the first opening 115 may have shape of, for example, an oval, a rectangle, a square with rounded corners, etc. In addition, in a plan view, the first openings 115 may be arranged in a lattice pattern, but the present invention is not limited thereto. That is, in a plan view, the first openings 115 may be arranged in, for example, a honeycomb pattern.

The second capacitor electrode 120 may cover the upper surface of the first capacitor electrode 100 exposed by the first opening 115 and a sidewall and an upper surface of the first mold 110 on the central portion C of the first substrate 10, and may cover the upper surface of the first capacitor electrode 100 on the peripheral portion P of the first substrate 10.

The first dielectric layer 130 may be formed on the second capacitor electrode 120.

The third capacitor electrode 140 may be disposed on the first dielectric layer 130 and fill a remaining portion of the first opening 115. Accordingly, the third capacitor electrode 140 may have a cylindrical/rectangular (e.g., pillar) shape.

In a plan view, the third capacitor electrode 140 may have a shape of a circle, but the present invention is not limited thereto. That is, in a plan view, the third capacitor electrode 140 may have a shape of, for example, an oval, a rectangle, a square with rounded corners, etc. In addition, in a plan view, the third capacitor electrodes 140 may be arranged in a lattice pattern, but the present invention is not limited thereto. That is, in a plan view, the third capacitor electrodes 140 may be arranged in, for example, a honeycomb pattern.

Each of the first and second capacitor electrodes 100 and 120 may include, for example, a metal, a metal nitride, a metal silicide, silicon-germanium doped with impurities. The first and second capacitor electrodes 100 and 120 may include different materials and may be distinguished from each other, or the first and second capacitor electrodes 100 and 120 may include the same material and be merged with each other.

The first dielectric layer 130 may include a ferroelectric material, an antiferroelectric material, a paraelectric material or a combination thereof. Ferroelectric materials may include, for example, a perovskite structure such as barium titanium oxide (BaTiOₓ), a fluorite structure of hafnium (Hf), hafnium zirconium oxide (HfₓZr₁₋ₓO_{y}), etc. Antiferroelectric materials may include, for example, zirconium oxide (ZrO₂), hafnium zirconium oxide (HfₓZr₁₋ₓO_{y}), lead zirconium oxide (PbZrO₃), sodium niobium oxide (NaNbO₃), etc. Additionally, a fluorite structure of hafnium (Hf) or hafnium zirconium oxide (HfₓZr₁₋ₓO_{y}) doped with rare earth elements such as aluminum (Al), barium (Ba), silicon (Si), yttrium (Y), scandium (Sc), strontium (Sr), lanthanum (La), etc., may be ferroelectric or antiferroelectric materials depending on the formulation. Paraelectric materials may include, for example, an oxide of Group 2 elements such as beryllium oxide (BeO₂), magnesium oxide (MgO₂), calcium oxide (CaO₂), strontium oxide (SrO₂), etc., an oxide of Group 3 elements such aluminum oxide (Al₂O₃), iridium oxide (Y₂O₃), scandium oxide (Sc₂O₃), lanthanum oxide (La₂O₃), etc., an oxide of Group 4 elements such as hafnium oxide (HfO₂), zirconium oxide (ZrO₂), titanium oxide (TiO₂), etc., an oxide of Group 5 elements such as tantalum oxide (Ta₂O₅), niobium oxide (Nb₂O₅), vanadium oxide (V₂O₅), high dielectric materials such as strontium titanium oxide (SrTiO₃), vanadium strontium titanium oxide (BaSrTiO₃), etc.

The third capacitor electrode 140 may include, for example, a metal, a metal nitride, a metal silicide, silicon-germanium doped with impurities, etc.

The first insulating interlayer 200 may be disposed on a portion of the first dielectric layer 130 on the peripheral portion P of the first substrate 10. The first insulating interlayer 200 may include, for example, an oxide such as silicon oxide or a low dielectric material. In example embodiments, an upper surface of the first insulating interlayer 200 and an upper surface of the first capacitor structure 150 may be substantially coplanar.

The second mold 210 may extend in the first direction D1 on the central portion C of the first substrate 10, and a plurality of second molds 210 may be spaced apart from each other in the second direction D2.

In example embodiments, the second mold 210 may include a first portion and a second portion sequentially stacked in the third direction D3. The first portion of the second mold 210 may have a first width in the second direction D2, and the second portion of the second mold 210 may have a second width that is smaller than the first width. Accordingly, a cross-section in the second direction D2 (e.g., in the D2-D3 plane) of the second mold 210 may have a shape of a reversed “T”.

The first gate structure 240 may include a first gate electrode 220 and a first gate insulation pattern 230 that are sequentially stacked on a sidewall in the second direction D2 of the second mold 210.

In example embodiments, the first gate insulation pattern 230 may cover a sidewall and an upper surface of the first gate electrode 220.

The first gate structure 240 may formed at each of opposite sidewalls in the second direction D2 of the second mold 210, but the present invention is not limited thereto. That is, the first gate structure 240 may be formed at only one of the opposite sidewalls in the second direction D2 of the second mold 210.

Hereinafter, the second mold 210 and the first gate structures 240 at each of the opposite sidewalls in the second direction D2 of the second mold 210 may be together referred to as an extension structure. The extension structure may extend in the first direction D1, and a plurality of extension structures may be spaced apart from each other in the second direction D2.

The channel 280 may be formed on the third capacitor electrode 140 and the first gate structure 240. Accordingly, a plurality of channels 280 may be spaced apart from each other in the first and second directions D1 and D2.

The channel 280 may include, for example, at least one semiconductor material having a band gap energy greater than that of polycrystalline silicon (i.e., polysilicon), for example, greater than about 1.65 eV. The semiconductor materials may include, for example, zinc tin oxide (ZnₓSn_{y}O, ZTO), indium zinc oxide (InₓZn_{y}O, IZO), zinc oxide (ZnₓO), indium gallium zinc oxide (InₓGa_{y}Zn_{z}O, IGZO), indium gallium silicon oxide (InₓGa_{y}Si_{z}O, IGSO), indium tungsten oxide (InₓW_{y}O, IWO), indium oxide (InₓO), tin oxide (SnₓO), titanium oxide (TiₓO), zinc oxynitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), etc. Accordingly, the channel 280 may be formed by a deposition process.

In example embodiments, the channel 280 may include vertical portions formed at each opposite sidewalls in the second direction D2 of the extension structure and a horizontal portion that is disposed on an upper surface of the extension structure to connect the vertical portions of the channel 280 to each other. Accordingly, a cross-section in the second direction D2 of the channel 280 may have a reversed “U” shape.

However, the present invention is not limited thereto. That is, the channel 280 may have a “U” shape with the horizontal portion disposed at a lower surface of the extension structure. Or, the channel 280 may have a “l” shape by including only the vertical portion.

A landing pad may be further disposed between the third capacitor electrode 140 and the vertical portion of the channel 280.

The third mold 260 may be disposed on a portion of the capacitor structure 250 on the central portion C of the first substrate 10 to fill space between the channels 280.

In example embodiments, the third mold 260 includes third portions and fourth portions. Each of the third portions may extend in the first direction D1 between ones of the channels 280 adjacent to each other in the second direction D2. Each of the fourth portions may connect neighboring ones of the third portions of the third mold 260 in the second direction D2 between neighboring ones of channels 280 in the first direction D1.

The fourth mold 265 may be formed on the first insulating interlayer 200 on the peripheral portion P of the first substrate 10.

In example embodiments, upper surfaces of the third and fourth molds 260 and 265 and an upper surface of the channel 280 may be substantially coplanar.

The bit line 310 may extend in the second direction D2 on the channels 280 that are arranged along the second direction D2, and a plurality of bit lines 310 may be spaced apart from each other in the first direction D1. In example embodiments, the bit line 310 may include a conductive material such as a metal, a metal nitride, a metal silicon nitride, etc.

A bit line shield may be formed between neighboring ones of the bit lines 310 in the first direction D1.

In example embodiments, the bit line shield may have a line type. That is, the bit line shield may extend in the second direction D2 between the neighboring ones of the bit lines 310 in the first direction D1, and a plurality of bit line shields may be spaced apart from each other in the first direction D1. Alternatively, the bit line shield may have a plate type. That is, the bit line shield may include a bit line shield plate and a bit line shield fin. The bit line shield may have a shape of a plate that is substantially parallel to the upper surface of the first substrate 10. The bit line shield fin may protrude from the bit line shield plate in the third direction D3 and extend in the second direction D2, and a plurality of bit line shield fins may be spaced apart from each other in the first direction D1.

The second insulating interlayer 300 may be disposed on the third and fourth molds 260 and 265 to cover a sidewall of the bit line 310.

The first contact plug 332 may be electrically connected to the bit line 310. The second contact plug may be electrically connected to the first gate electrode 220. The third contact plug 336 may be electrically connected to the capacitor electrode structure 125. The first contact plug 332, the second contact plug and the third contact plug 336 may be in contact with upper surfaces of the bit line 310, the first gate electrode 220 and the capacitor electrode structure 125, respectively. However, the present invention is not limited thereto.

The first to third wirings 342, 344 and 346 may be disposed on the first contact plug 332, the second contact plug and the third contact plug 336, respectively.

In example embodiments, each of widths in the horizontal direction of the first contact plug 332, the second contact plug, the third contact plug 336 and the first to third wirings 342, 344 and 346 may increase in the third direction D3 away from the upper surface of the first substrate 10.

The third insulating interlayer 350 may cover the first contact plug 332, the second contact plug, the third contact plug 336 and the first to third wirings 342, 344 and 346.

The bonding region III, in/on which structures that bond the cell array region I and the central circuit region II are formed, may include first and second bonding layers 360 and 510. The first bonding layer 360 and the second bonding layer 510 may individually or collectively be referred to herein as a “bonding structure.” The bonding structure may bond the cell array region I and the central circuit region II to each other. In some embodiments, the first bonding layer 360 and the second bonding layer 510 may directly contact the cell array region I and the central circuit region II, respectively.

The first and second bonding layers 360 and 510 may be sequentially formed on the third insulating interlayer 350 in the third direction D3. Each of the first and second bonding layers 360 and 510 may include, for example, silicon carbonitride (SiCN).

Each of the first to third insulating interlayers 200, 300 and 350 may include, for example, an oxide such as silicon oxide or a low dielectric material. Each of the first to third contact plugs 332, 334 and 336 and the first to third wirings 342, 344 and 346 may include conductive materials such as a metal, a metal nitride, a metal silicide, polysilicon doped with impurities, etc.

The central circuit region II may include a central circuit pattern that performs a routing operation. The central circuit pattern may include, for example, bit line sense amplifier (BLSA), sub-word line driver (SWD), column decoder, column select line (Common Select Line: CSL) driver, input/output sense amplifier (I/O SA), write driver, etc.

The central circuit region II may include a transistor, a fourth contact plug 440, fourth to sixth wirings 450, 470 and 490, first and second vias 460 and 480 and a fourth insulating interlayer 500 on the second substrate 20.

The semiconductor device may have a Core On Cell (COC) structure in which a central circuit region II is formed on the cell array region I, but the present invention is not limited thereto. Alternatively, the semiconductor device may have a Cell on Core (COC) structure in which the cell array region I is formed on the central circuit region II.

The second substrate 20 may include a semiconductor material, e.g., silicon, germanium, silicon-germanium, etc., or a group III-V compound semiconductor, e.g., GaP, GaAs, GaSb, etc. In example embodiments, the second substrate 20 may be a silicon-on-insulator (SOI) substrate or a germanium-on-insulator (GOI) substrate.

The transistor may include a second gate structure 435 on the second substrate 20 and source/drain regions (e.g., layers) 22 at an upper portion of the second substrate 20 adjacent to the second gate structure 435.

The second gate structure 435 may include a second gate insulation pattern 410, a second gate electrode 420 and a capping pattern 430 sequentially stacked in the third direction D3. In an example embodiment, the second gate structure 435 may extend in the first direction D1, and a plurality of second gate structures 435 may be spaced apart from each other in the second direction D2. A gate spacer may be formed at opposite sidewalls of the second gate structure 435.

The second gate insulation pattern 410 may include, for example, an oxide such as silicon oxide, the second gate electrode 420 may include a conductive material such as a metal, a metal nitride, a metal silicide, polysilicon doped with impurities, etc., and the capping pattern 430 may include, for example, a nitride such as silicon nitride.

The transistor is illustrated as a planar type in the figures, but the present invention is not limited thereto, and the transistor may be a Fin Field Effect Transistor (FinFET), Multi-Bridge Channel Field Effect Transistor (MBCFET), etc.

Each of the source/drain regions 22 may include n-type impurities, such as phosphorus, arsenic, etc., or p-type impurities, such as boron, aluminum, etc.

The fourth contact plug 440, the fourth wiring 450, the first via 460, the fifth wiring 470, the second via 480 and the sixth wiring 490 may be sequentially stacked in the third direction D3, and the fourth contact plug 440 may contact an upper surface of the source/drain region 22. Each of the fourth contact plug 440, the fourth to sixth wirings 450, 470 and 490 and the first and second vias 460 and 480 may include a conductive material such as a metal, a metal nitride, a metal silicide, polysilicon doped with impurities, etc.

In example embodiments, a width in the horizontal direction of each of the fourth contact plug 440, the fourth to sixth wirings 450, 470 and 490 and the first and second vias 460 and 480 may increase in the third direction D3 away from the upper surface of the first substrate 10.

The fourth insulating interlayer 500 may be formed on the second substrate 20 to cover the transistor, the fourth to sixth wirings 450, 470 and 490 and the first and second vias 460 and 480. The fourth insulating interlayer 500 may include, for example, an oxide such as silicon oxide or a low dielectric material.

In the wiring region IV, structures connecting the cell array region I to the peripheral circuit region or the central circuit region II to the peripheral circuit region may be formed. The wiring region IV may include a fifth contact plug 540, seventh to ninth wirings 550, 570 and 590, third and fourth vias 560 and 580 and a fifth insulating interlayer 600. In some embodiments, the fifth contact plug 540 may electrically connect the cell array region I to the peripheral circuit region or the central circuit region II to the peripheral circuit region. According to some embodiments, the contact plug 540 overlaps, in the third (vertical) direction D3, a portion of the first capacitor structure 150 that is on the peripheral portion P of the first substrate 10. For example, the contact plug 540 may overlap the first capacitor electrode 100 and the second capacitor electrode 120 in the third direction D3, and not overlap the third capacitor electrode 140 in the third direction D3 (as the third capacitor electrode 140 may be on the central portion C and not on the peripheral portion P). Likewise, the contact plug 540 may not overlap the first gate structure 240, the channel 280, or the bit line 310 in the third direction D3, as they may be on the central portion C and not on the peripheral portion P. Moreover, the second capacitor electrode 120 may be between, in the third direction D3, the first capacitor electrode 100 and the third capacitor electrode 140.

The fifth contact plug 540 may extend through a lower portion of the fifth insulating interlayer 600 and an upper portion of the fourth insulating interlayer 500 to contact an upper surface of the sixth wiring 490, or may extend through the lower portion of the fifth insulating interlayer 600, the fourth insulating interlayer 500, the second substrate 20, the second bonding layer 510, the first bonding layer 360 and an upper portion of the third insulating interlayer 350 to contact an upper surface of the second wiring or an upper surface of the third wiring 346.

The seventh wiring 550, the third via 560, the eighth wiring 570, the fourth via 580 and the ninth wiring 590 may be sequentially stacked in the third direction D3, and the seventh wiring 550 may contact an upper surface of the fifth contact plug 540. Each of the fifth contact plug 540, the seventh to ninth wirings 550, 570 and 590 and the third and fourth vias 560 and 580 may include a conductive material such as a metal, a metal nitride, a metal silicide, polysilicon doped with impurities, etc.

In example embodiments, a width in the horizontal direction of each of the fifth contact plug 540, the seventh to ninth wirings 550, 570 and 590 and the third and fourth vias 560 and 580 may increase in the third direction D3 away from the upper surface of the first substrate 10.

The fifth insulating interlayer 600 may be formed on the fourth insulating interlayer 500 to cover the fifth contact plug 540, the seventh to ninth wirings 550, 570 and 590 and the third and fourth vias 560 and 580. The fifth insulating interlayer 600 may include, for example, an oxide such as silicon oxide or a low dielectric material.

In the semiconductor device, current may flow in the third direction D3, that is, in the vertical direction, within the channel 280 that is disposed between the bit line 310 and the third capacitor electrode 140. Accordingly, the semiconductor device may include a vertical channel transistor (VCT) including a vertical channel.

The semiconductor device according to example embodiments may have a Core Over Cell structure in which the central circuit region II is formed on the cell array region I.

In contrast, if the semiconductor device has a Cell Over Core structure in which the cell array region I is formed on the central circuit region II, for example, the fifth contact plug 540 of the wiring region IV contacting the upper surface of the sixth wiring 490 of the central circuit region II should be formed to be longer by a length of the central circuit region II in the third direction D3. Accordingly, difficulty and cost of forming the fifth contact plug 540 may increase.

However, the semiconductor device according to example embodiments may have a Core Over Cell structure, and thus, the aspect ratio of the fifth contact plug 540 may decrease, thereby reducing overall process difficulty and cost.

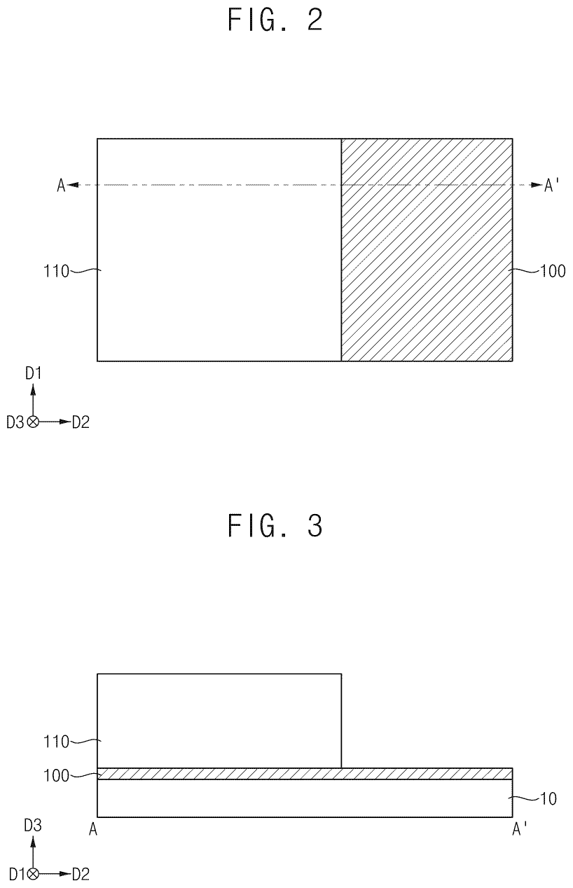

FIGS. 2 to 25 are plan views and cross-sectional views illustrating a method of manufacturing a semiconductor device according to example embodiments. Specifically, FIGS. 2, 4, 6, 8, 10, 12, 14, 16, 18, 20 and 22 are the plan views and FIGS. 3, 5, 7, 9, 11, 13, 15, 17, 19, 21 and 23-25 are cross-sectional views taken along lines A-A′, respectively, of corresponding plan views.

Referring to FIGS. 2 and 3, a first capacitor electrode 100 and a first mold 110 may be sequentially formed in the third direction D3 on a first substrate 10.

The first mold 110 may be formed on a central portion C of the first substrate 10. Accordingly, an upper surface of the first capacitor electrode 100 on a peripheral portion P of the first substrate 10 may be exposed and not be covered by the first mold 110.

Referring to FIGS. 4 and 5, a portion of the first mold 110 may be etched to form a first opening 115 exposing the upper surface of the first capacitor electrode 100.

In example embodiments, a plurality of first openings 115 may be spaced apart from each other in the first and second directions D1 and D2 to form a first opening array on the central portion C of the first substrate 10. The first opening array may include a plurality of first opening columns spaced apart from each other in the second direction D2. Each of the first opening columns may include the first openings 115 that are arranged in the first direction D1.

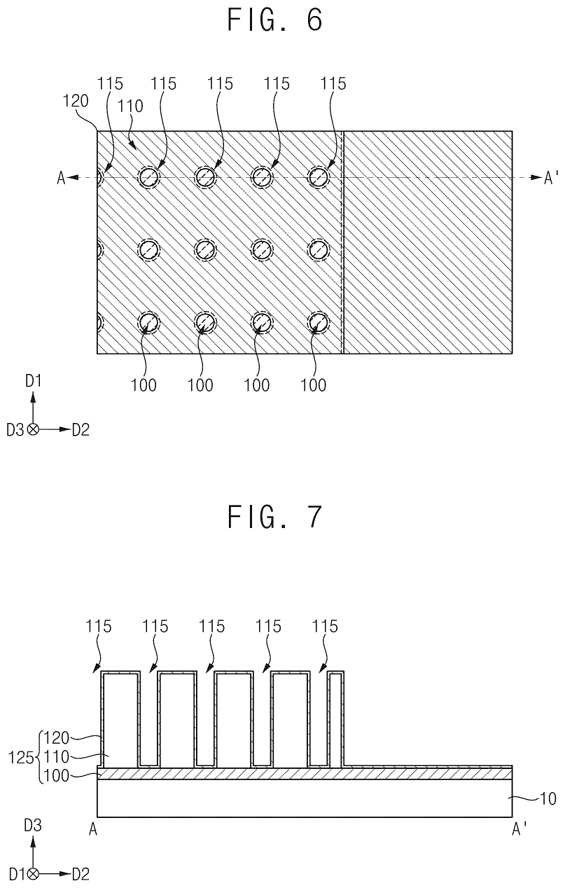

Referring to FIGS. 6 and 7, the second capacitor electrode 120 may be formed on the exposed upper surface of the first capacitor electrode 100, a sidewall and an upper surface of the first mold 110 and the upper surface of the first capacitor electrode 100 on the peripheral portion P of the first substrate 10. Accordingly, the first and second capacitor electrodes 100 and 120 may contact each other.

The first capacitor electrode 100, the first mold 110 and the second capacitor electrode 120 may together form a capacitor electrode structure 125.

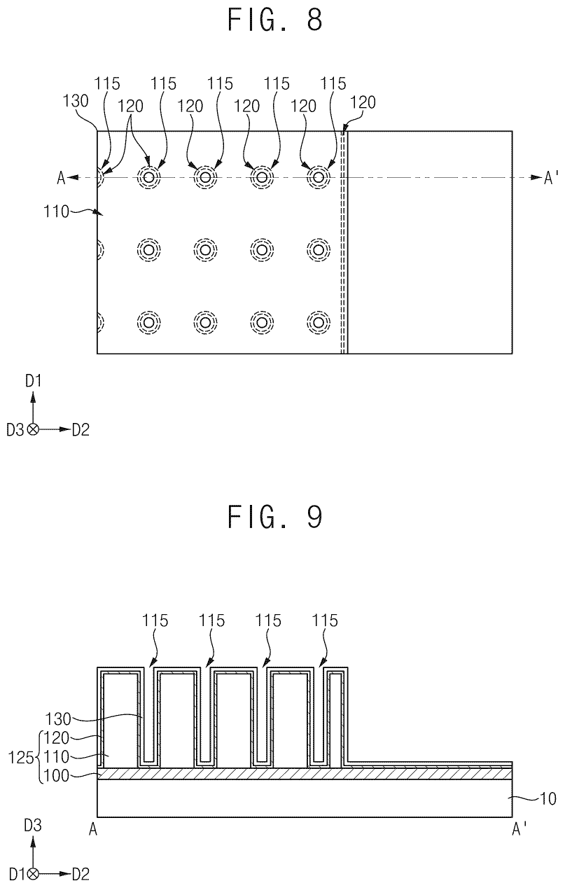

Referring to FIGS. 8 and 9, a first dielectric layer 130 may be formed on the capacitor electrode structure 125.

In example embodiments, the first dielectric layer 130 may be formed by a deposition process such as a chemical vapor deposition (CVD) process, an atomic layer deposition (ALD) process, a physical vapor deposition (PVD) process, etc.

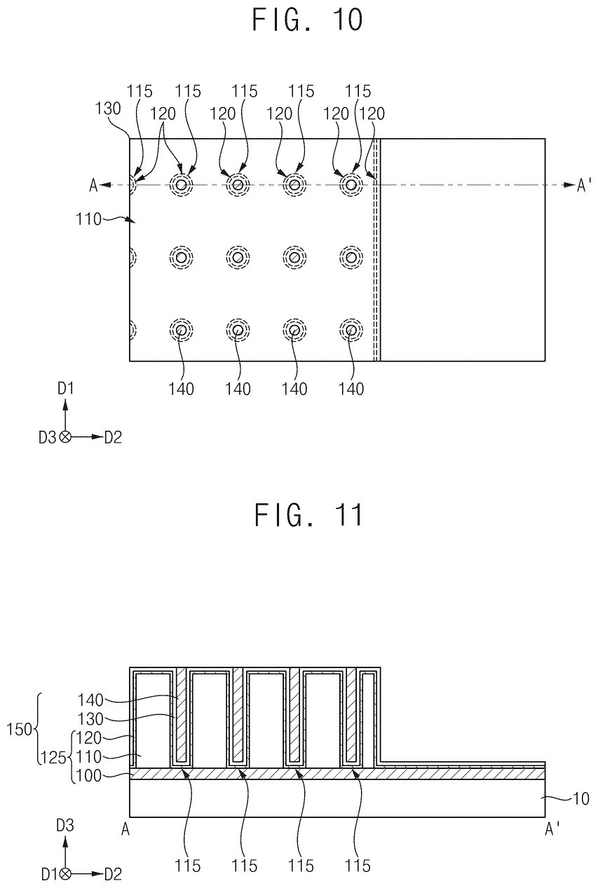

Referring to FIGS. 10 and 11, a third capacitor electrode 140 may be formed in (e.g., to fill) a remaining portion of the first opening 115.

In example embodiments, a plurality of third capacitor electrodes 140 may be spaced apart from each other in the first and second directions D1 and D2 to form a third capacitor electrode array on the central portion C of the first substrate 10. The third capacitor electrode array may include a plurality of third capacitor electrode columns spaced apart from each other in the second direction D2. Each of the third capacitor electrode columns may include the third capacitor electrodes 140 that are arranged in the first direction D1.

The capacitor electrode structure 125, the first dielectric layer 130 and the third capacitor electrode 140 may together form the first capacitor structure 150.

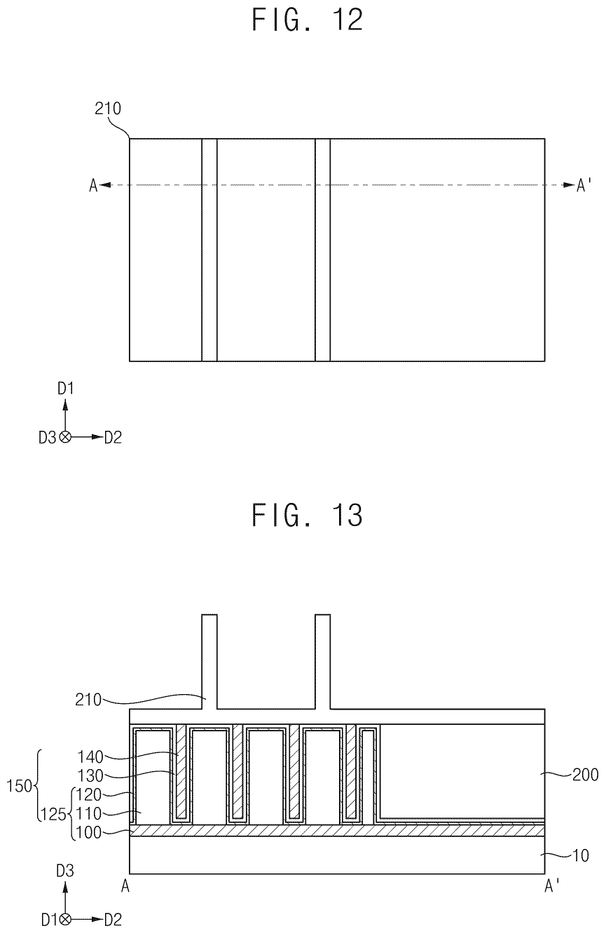

Referring to FIGS. 12 and 13, a first insulating interlayer 200 may be formed on the first capacitor structure 150 to a sufficient height, and a planarization process may be performed on an upper portion of the first insulating interlayer 200 until an upper surface of the first capacitor structure 150 is exposed.

The planarization process may include, for example, a chemical mechanical polishing (CMP) process and/or an etch back process.

A second mold 210 may be formed on the first capacitor structure 150 and the first insulating interlayer 200.

The second mold 210 may include a first portion covering the first capacitor structure 150 and the first insulating interlayer 200 and a second portion protruding from the first portion in the third direction D3. The second portion may extend in the first direction D1 between neighboring ones of the third capacitor electrode rows in the second direction D2, and a plurality of second portions may be spaced apart from each other in the second direction D2.

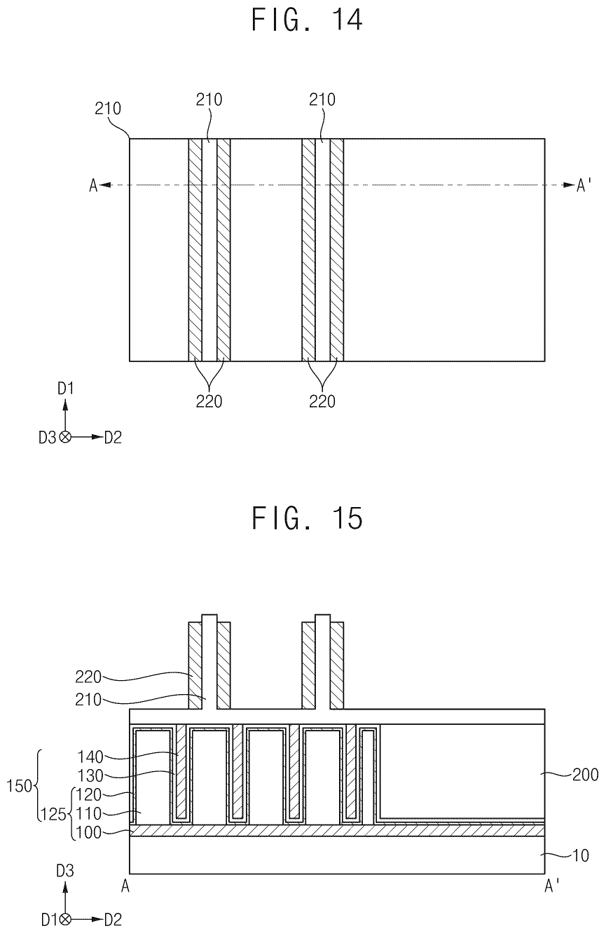

Referring to FIGS. 14 and 15, a first gate electrode 220 may be formed to extend in the first direction D1 along a sidewall in the second direction D2 of the second portion of the second mold 210. Accordingly, a plurality of first gate electrodes 220 may be formed to be spaced apart from each other along the second direction D2.

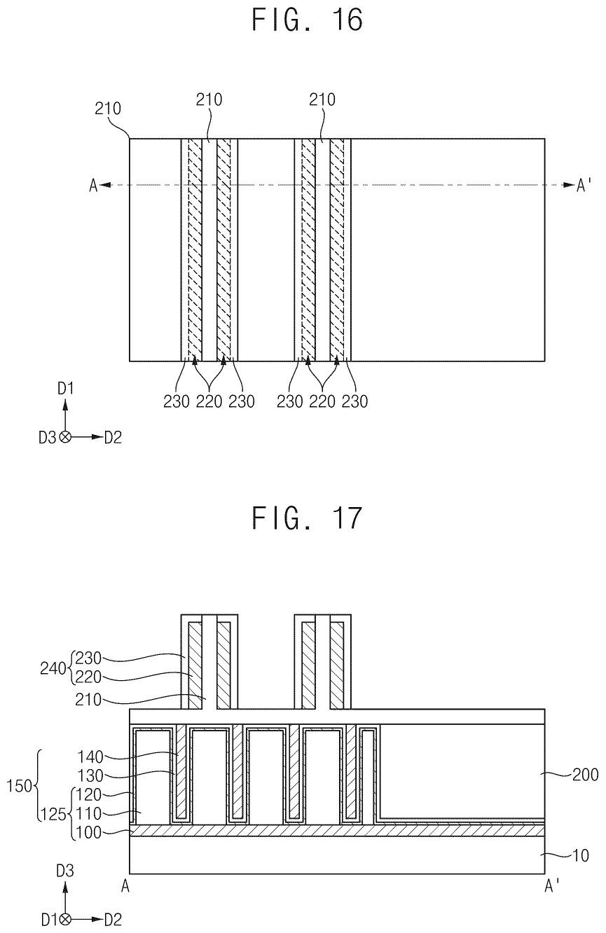

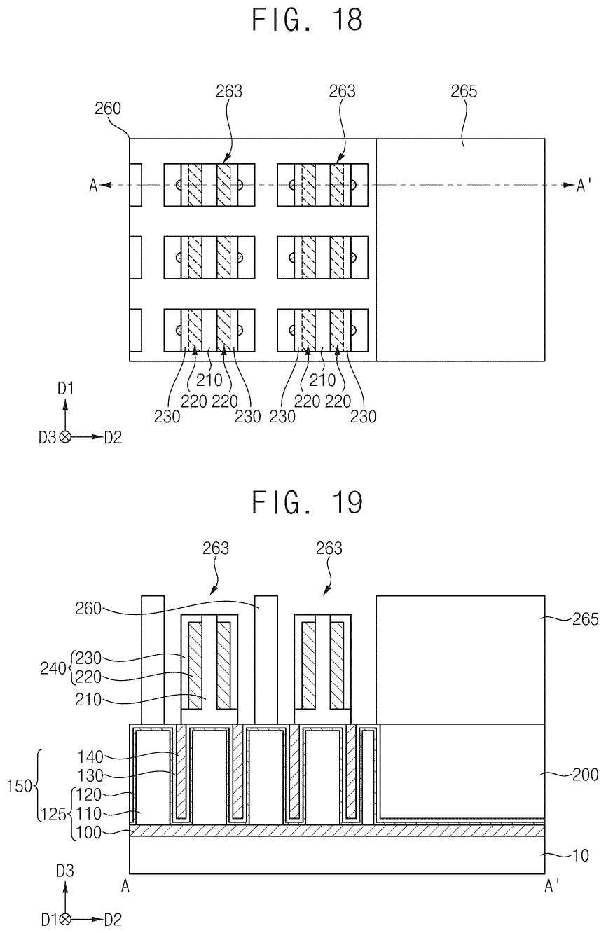

Referring to FIGS. 16 and 17, a first gate insulation pattern 230 may be formed to extend in the first direction D1 along an upper surface and a sidewall in the second direction D2 of the first gate electrode 220. Accordingly, a plurality of first gate insulation patterns 230 may be formed to be spaced apart from each other along the second direction D2.

The first gate electrode 220 and the first gate insulation pattern 230 may together form the first gate structure 240. In example embodiments, the first gate structure 240 may extend in the first direction D1, and a plurality of first gate structures may be spaced apart from each other along the second direction D2.

Referring to FIGS. 18 and 19, the first portion of the second mold 210 formed between neighboring ones of the first gate structures 240 in the second direction D2 may be removed/patterned. Accordingly, the first portion of the second mold 210 may be separated into a plurality of parts that are spaced apart from each other in the second direction D2, and an upper surface of the first dielectric layer 130 between the neighboring ones of the first gate structures 240 in the second direction D2 may be exposed.

Hereinafter, the second mold 210 and the first gate structures 240 formed at each of the opposite sidewalls in the second direction D2 of the second mold 210 may together be referred to as an extension structure.

A mold may be formed on the first dielectric layer 130, the third capacitor electrodes 140 and the extension structure to a sufficient height. A second opening 263 may be formed to extend through the mold and expose an upper surface of the third capacitor electrode 140.

In example embodiments, the second opening 263 may be formed to expose upper surfaces of a pair of the third capacitor electrodes 140 adjacent to the extension structure in the second direction D2 and an upper surface of the extension structure.

In a plan view the second opening 263 may have a shape of a rectangle, but the present invention is not limited thereto. That is, in a plan view, the second opening 263 may have a shape of, for example, a circle, an oval, a square with rounded corners, etc. Additionally, in a plan view, a plurality of second openings 263 may be arranged in a lattice pattern, but the present invention is not limited thereto. That is, in a plan view, the second opening 263 may be arranged in, for example, a honeycomb pattern.

Hereinafter, a portion of the mold including the second opening 263 on the central portion C of the first substrate 10 may be referred to as a third mold 260, and a portion of the mold on the peripheral portion P of the first substrate 10 may be referred to as a fourth mold 265.

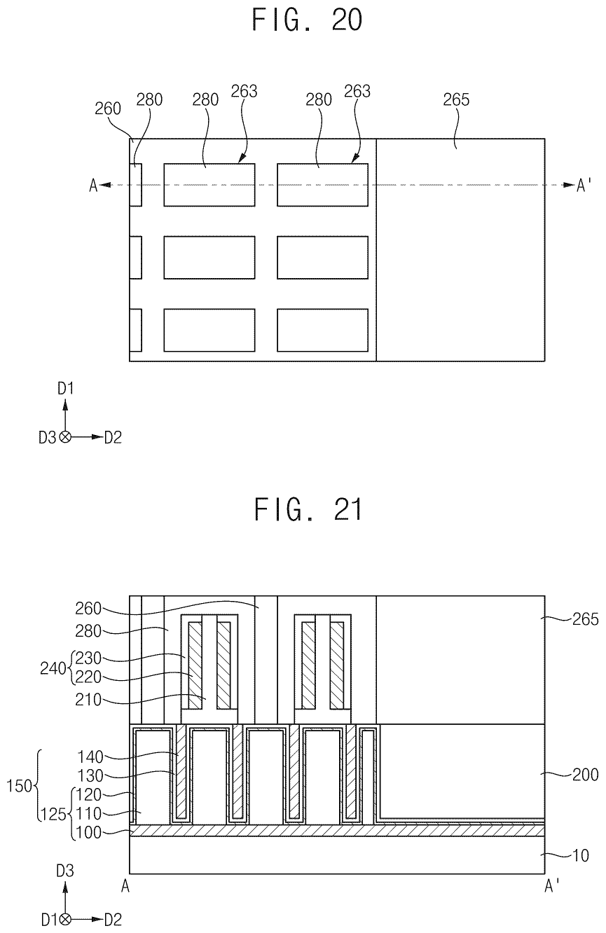

Referring to FIGS. 20 and 21, a deposition process may be performed to form a channel layer in (e.g., filling) the second opening 263 to a sufficient height, and a planarization process may be performed on an upper portion of the channel layer until upper surfaces of the third and fourth molds 260 and 265 are exposed to form a channel 280. Accordingly, a plurality of channels 280 may be spaced apart from each other in the first and second directions D1 and D2.

In example embodiments, the planarization process may include a chemical mechanical polishing (CMP) process and/or an etch back process.

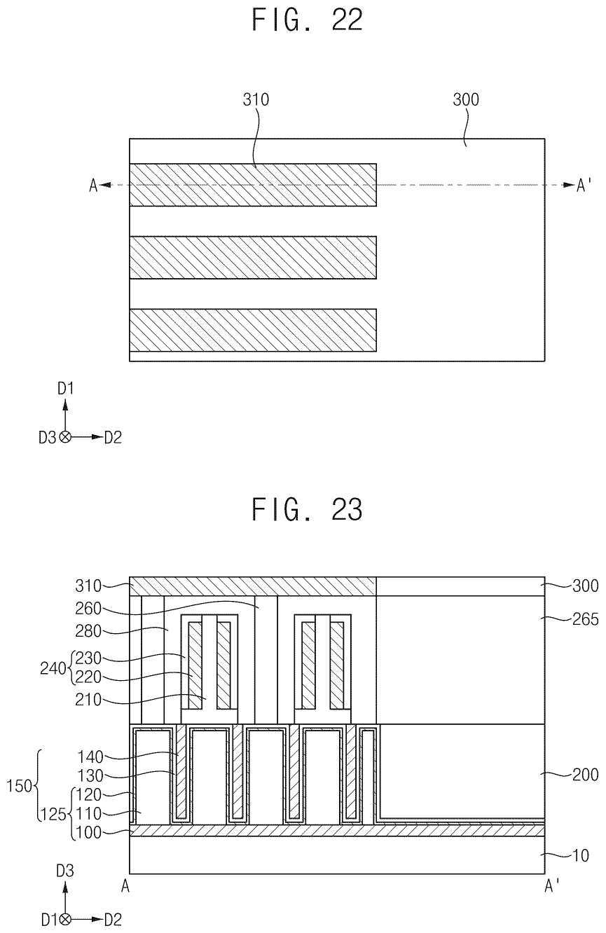

Referring to FIGS. 22 and 23, a bit line 310 and a second insulating interlayer 300 covering a sidewall of the bit line 310 may be formed.

In an example embodiment, the bit line 310 and the second insulating interlayer 200 may be formed by forming a conductive layer on the channel 280 and the third and fourth molds 260 and 265, dividing the conductive layer into a plurality of bit lines 320 by a patterning process, forming the second insulating interlayer 200 to a sufficient height on the bit line 310, and performing a planarization process on an upper portion of the second insulating interlayer 200 until an upper surface of the bit line 310 is exposed. In another example embodiment, the bit line 310 and the second insulating interlayer 200 may be formed by forming the second insulating interlayer 200 on the channel 280 and the third and fourth molds 260 and 265, forming a third opening that commonly exposes upper surfaces of the channels 280 arranged along the second direction D2, forming a conductive layer to a sufficient height within the third opening, and performing a planarization process on an upper portion of the conductive layer until an upper surface of the second insulating interlayer 200 is exposed to divide the conductive layer into the plurality of bit lines 310.

In example embodiments, the bit line 310 may extend in the second direction D2 on the channels 280 arranged along the second direction D2. Accordingly, the bit lines 310 may be spaced apart from each other along the first direction D1.

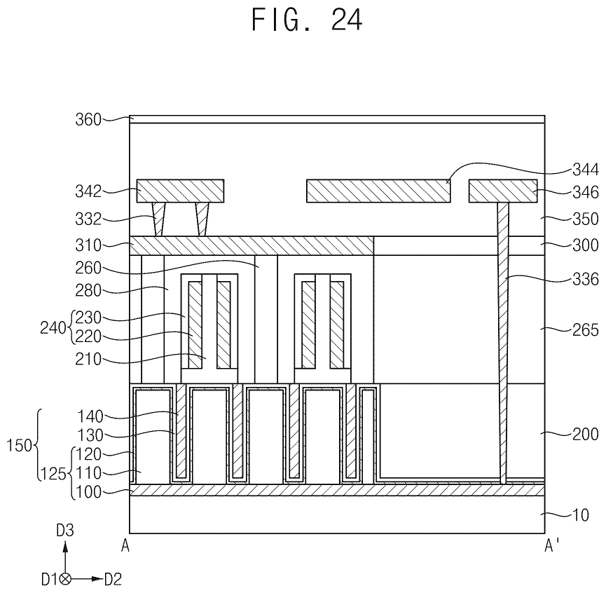

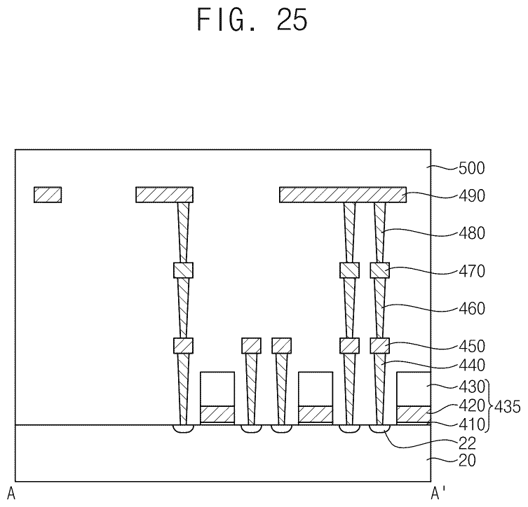

Referring to FIG. 24, a first contact plug 332, a second contact plug, a third contact plug 336, first to third wirings 342, 344 and 346 and a third insulating interlayer 350 covering the first contact plug 332, the second contact plug, the third contact plug 336, the first to third wirings 342, 344 and 346 may be formed.

The first contact plug 332 may be formed to be electrically connected to the bit line 310. The second contact plug may be formed to be electrically connected to the first gate electrode 220. The third contact plug 336 may be formed to extend through the second insulating interlayer 300, the fourth mold 265 and the first dielectric layer 130 to be electrically connected to the capacitor electrode structure 125. The first to third wirings 342, 344 and 346 may contact upper surfaces of the first contact plug 332, the second contact plug, and the third contact plug 336, respectively. The first contact plug 332, the second contact plug, and the third contact plug 336 may collectively be referred to herein as “first contact plugs,” and may be electrically connected to the bit line 310, the first gate electrode 220, and the first capacitor structure 150 (e.g., the capacitor electrode structure 125 thereof), respectively.

Structures on the first substrate 10 may together form a cell array region II.

A first bonding layer 360 may be formed on the third insulating interlayer 350.

Referring to FIG. 25, a transistor may be formed on a second substrate 20. The transistor may include a second gate structure 435 on the second substrate 20 and source/drain regions/layers 22 on an upper portion of the second substrate 20 adjacent to the second gate structure 435. The second gate structure 435 may include a second gate insulation pattern 410, a second gate electrode 420 and a capping pattern 430 sequentially stacked.

A fourth contact plug 440, a fourth wiring 450, a first via 460, a fifth wiring 470, a second via 480 and a sixth wiring 490 sequentially stacked in the third direction D3 on the source/drain region 22 and a fourth insulating interlayer 500 covering the fourth contact plug 440, the fourth wiring 450, the first via 460, the fifth wiring 470, the second via 480 and the sixth wiring 490 may be formed.

Structures on the second substrate 20 may together form the central circuit region II.

Referring to FIG. 1 again, the second substrate 20 may be turned over, and a second bonding layer 510 may be formed on a lower surface of the second substrate 20. Thereafter, the second bonding layer 510 and the first bonding layer 360 may contact (i.e., directly, physically contact) each other so that the second substrate 20 and the first substrate 10 may be bonded with each other.

The first and second bonding layers 360 and 510 may together form a bonding region III.

A fifth contact plug 540, seventh to ninth wirings 550, 570 and 590, third and fourth vias 560 and 580 and a fifth insulating interlayer 600 covering the fifth contact plug 540, the seventh to ninth wirings 550, 570 and 590 and the third and fourth vias 560 and 580 may be formed on the fourth insulating interlayer 500 of the central circuit region II.

The fifth contact plug 540 may extend through a lower portion of the fifth insulating interlayer 600 and an upper portion of the fourth insulating interlayer 500 to contact an upper surface of the sixth wiring 490, or may extend through the lower portion of the fifth insulating interlayer 600, the fourth insulating interlayer 500, the second substrate 20, the second bonding layer 510, the first bonding layer 360 and an upper portion of the third insulating interlayer 350 to contact an upper surface of the second wiring or an upper surface of the third wiring 346.

The seventh wiring 550, the third via 560, the eighth wiring 570, the fourth via 580 and the ninth wiring 590 may be sequentially stacked in the third direction D3 within the fifth insulating interlayer 600, and the seventh wiring 550 may contact an upper surface of the fifth contact plug 540.

Accordingly, a width in the horizontal direction of each of the fifth contact plug 540, the seventh to ninth wirings 550, 570 and 590 and the third and fourth vias 560 and 580 may increase in the third direction D3 away from the upper surface of the first substrate 10.

Structures formed on the cell array region I and the central circuit region II may together form a wiring region IV.

In the method of manufacturing the semiconductor device, the cell array region I and the central circuit region II may be formed through separate processes, the first bonding layer 360 may be formed on the cell array region I, the second bonding layer 510 may be formed on the central circuit region II, and the first and second bonding layers 360 and 510 may be bonded to each other to form a Core Over Cell structure where the central circuit region II is formed on the cell array region I.

In contrast, when the central circuit region II, the cell array region I and the wiring region IV are sequentially formed on the first substrate 10, layout of structures (for example, contact plugs, wirings, vias, etc.) included in the wiring region IV may be limited. Accordingly, a mismatch, where there is a difference between signals arriving the cell array region I, may occur.

However, in the semiconductor device according to example embodiments, the separately formed cell array region I and the central circuit region II may be bonded to each other by the bonding region IV. Thus, the top and bottom of the cell array region I and the central circuit region II and arrangement of the structures of the wiring region IV may be easily adjusted as needed. Accordingly, deterioration of electrical characteristics of the semiconductor device due to mismatch may be decreased or prevented.

Additionally, the channel 280 may be formed by forming the channel layer to a sufficient height in (e.g., to fill) the second opening 263 that exposes the upper surface of the third capacitor electrode 140, and performing the planarization process on the upper portion of the channel layer until the upper surface of the third and fourth molds 260 and 265 are exposed. Accordingly, since the channel 280 may be formed without a patterning process on the channel layer, which is relatively difficult to pattern elaborately, process difficulty may be further reduced.

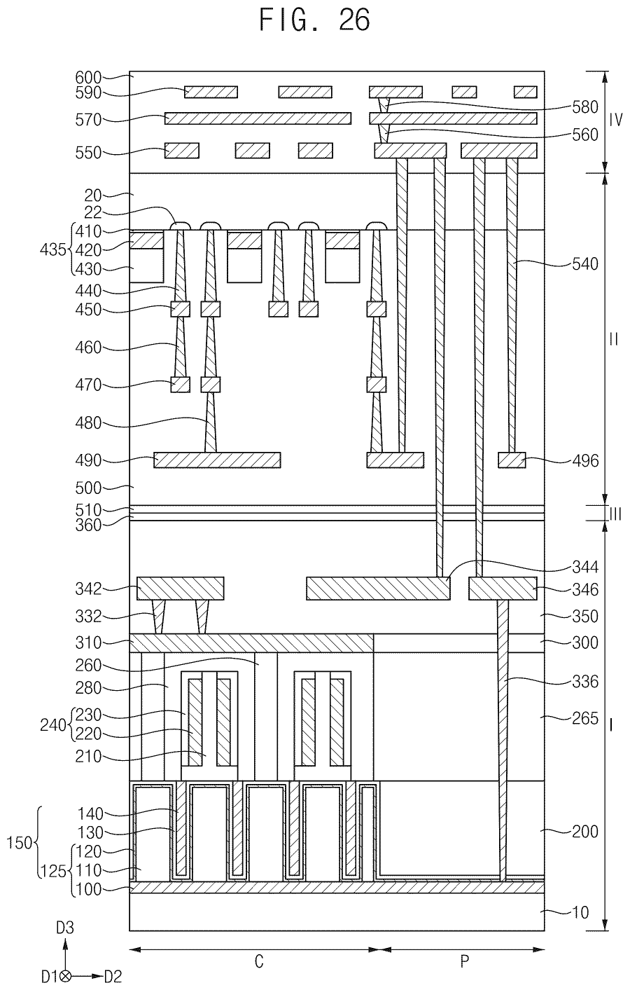

FIGS. 26 to 28 are cross-sectional views illustrating semiconductor devices in accordance with example embodiments. Each of the semiconductor devices may be substantially the same as or similar to that of FIG. 1, except for the structures of the bonding region III or the top and bottom of the central circuit region II.

Referring to FIG. 26, unlike the processes described with reference to FIG. 1, before turning over the second substrate 20, the second bonding layer 510 may formed on the fourth insulating interlayer 500. Thereafter, the second substrate 20 may be bonded to the first substrate 10 by contacting the second bonding layer 510 to the first bonding layer 360. Accordingly, unlike the semiconductor devices illustrated with reference to FIG. 1, the structures included in the central circuit region II may be turned upside down.

Accordingly, the width in the horizontal direction of each of the fourth contact plug 440, the fourth to sixth wirings 450, 470 and 490 and the first and second vias 460 and 480 may decrease in the third direction D3 away from the upper surface of the first substrate 10.

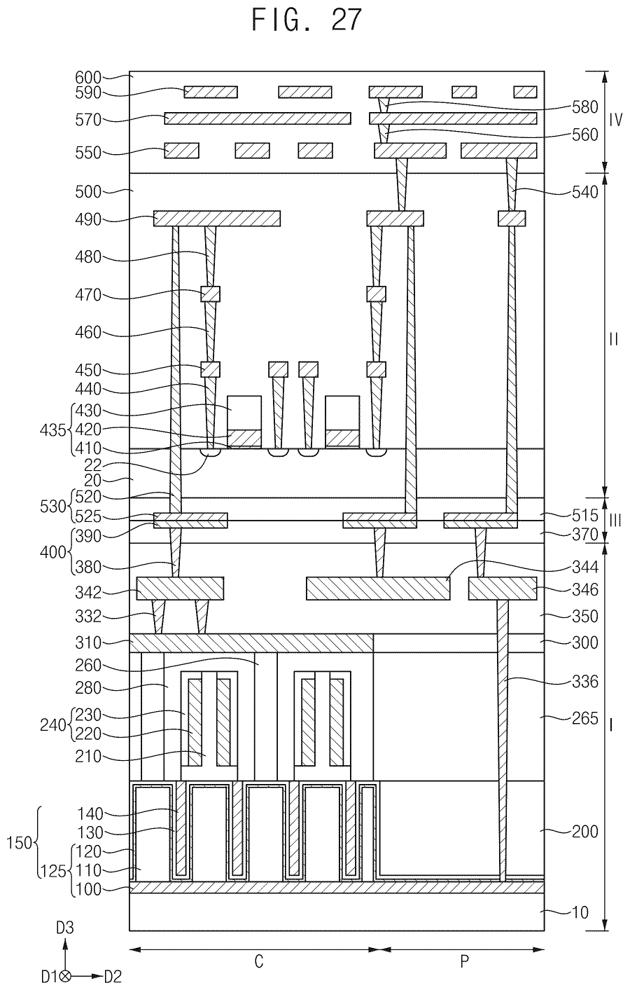

Referring to FIG. 27, unlike the processes illustrated with reference to FIG. 24, instead of the first bonding layer 360, a third bonding layer 370 and a first bonding structure 400 extending through the third bonding layer 370 may be formed on the third insulating interlayer 350.

The first bonding structure 400 may include a first bonding contact 380 and a first bonding pad 390 sequentially stacked in the third direction D3. A width in the horizontal direction of each of the first bonding contact 380 and the first bonding pad 390 may increase in the third direction D3 away from the upper surface of the first substrate 10.

A portion of the first bonding contact 380 may extend through a lower portion of the third bonding layer 370 and the upper portion of the third insulating interlayer 350 to contact upper surfaces of the first to third wirings 342, 344 and 346. However, the present invention is not limited thereto, and for example, the first bonding contact 380 may contact an upper surface of other wirings and/or vias additionally formed.

Processes substantially the same as or similar to those illustrated with reference to FIG. 25 may be performed.

Unlike processes illustrated with reference to FIG. 1, instead of the second bonding layer 510, a fourth bonding layer 515 and a second bonding structure 530 extending through the fourth bonding layer 515 may be formed on a lower surface of the second substrate 20.

The second bonding structure 530 may include a second bonding pad 525 and a second bonding contact 520 sequentially stacked in the third direction D3. A width in the horizontal direction of each of the second bonding pad 525 and the second bonding contact 520 may decrease in the third direction D3 away from the upper surface of the first substrate 10.

A portion of the second bonding contact 520 may extend through an upper portion of the fourth bonding layer 515 and a lower portion of the fourth insulating interlayer 500 to contact the upper surface of the sixth wiring 490. However, the present invention is not limited thereto, and for example, the second bonding contact 520 may contact upper surfaces of the fourth and fifth wirings 450 and 470 or upper surfaces of other wirings and/or vias additionally formed.

Each of the third and fourth bonding layers 370 and 515 may include an insulating material such as silicon carbonitride (SiCN), etc. Each of the first and second bonding pads 390 and 525 may include a metal such as copper, aluminum, etc. Each of the first and second bonding contacts 380 and 520 may include a conductive material such as a metal, a metal nitride, a metal silicide, polysilicon doped with impurities, etc.

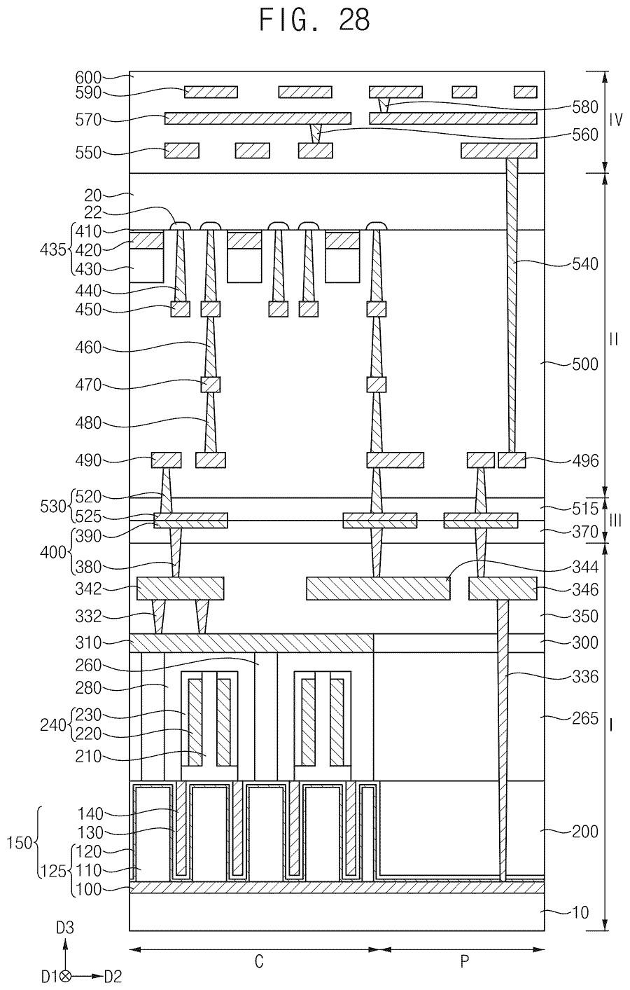

Referring to FIG. 28, unlike the processes illustrated with reference to FIG. 24, instead of the first bonding layer 360, the third bonding layer 370 and the first bonding structure 400 may be formed.

The third bonding layer 370 and the first bonding structure 400 may be substantially the same as or similar to that of FIG. 27, and thus repeated explanations are omitted herein.

Hereafter, unlike the processes illustrated with reference to FIG. 1, before turning over the second substrate 20, instead of the second bonding layer 510, the fourth bonding layer 515 and the second bonding structure 530 may be formed on the fourth insulating interlayer 500. The fourth bonding layer 515 and the second bonding structure 530 may be substantially the same as or similar to that of FIG. 27, and thus repeated explanations are omitted herein.

A portion of the second bonding contact 520 may extend through the upper portion of the fourth bonding layer 515 and the lower portion of the fourth insulating interlayer 500 to contact the upper surface of the sixth wiring 490. However, the present invention is not limited thereto, and, for example, the second bonding contact 520 may contact the upper surfaces of the fourth and fifth wirings 450 and 470 or upper surfaces of other wirings and/or vias additionally formed.

The semiconductor devices illustrated with reference to FIGS. 26 to 28 may be formed to have a Core On Cell (COC) structure in which the central circuit region II is formed on the cell array region I. However, depending on process margin, cost, characteristics of the semiconductor device, etc., the semiconductor device may be formed to have a Cell On Core (COC) structure in which the cell array region I is formed on the central circuit region II.

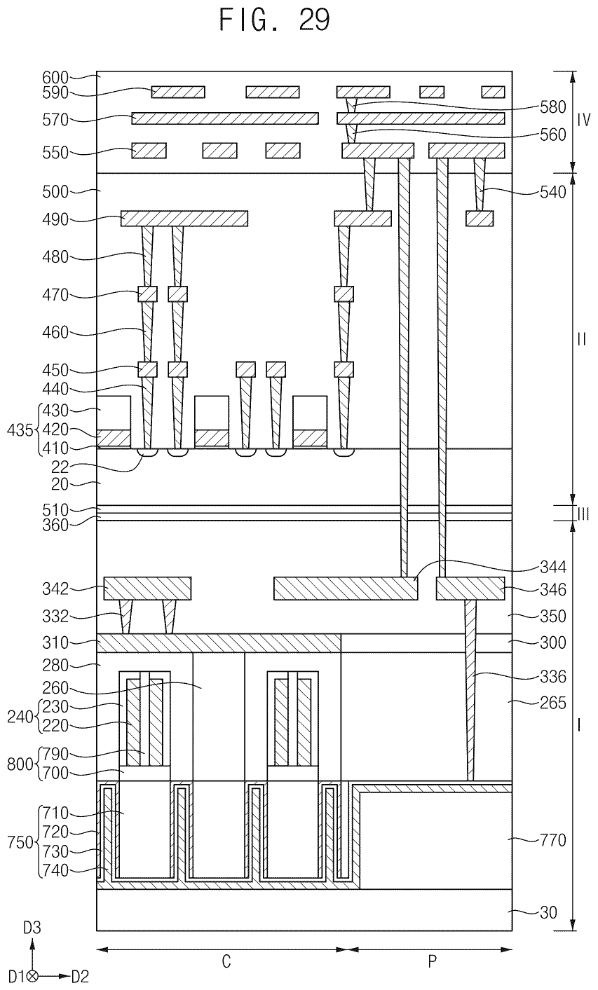

FIG. 29 is a cross-sectional view illustrating a semiconductor device in accordance with example embodiments. The semiconductor device may be substantially the same as or similar to that of FIG. 1, except for the cell array region I including a third substrate 30, an eighth insulating interlayer 770, a second capacitor structure 750 and a mold structure 800 instead of including the first substrate 10, the first insulating interlayer 200, the first capacitor structure 150 and the second mold 210.

The third substrate 30 may include a semiconductor material, e.g., silicon, germanium, silicon-germanium, etc., or a group III-V compound semiconductor, e.g., GaP, GaAs, GaSb, etc. In example embodiments, the third substrate 30 may be a silicon-on-insulator (SOI) substrate or a germanium-on-insulator (GOI) substrate.

In example embodiments, the third substrate 30 may include a central portion C where the second capacitor structure 750, the first gate structure 240, the channel 280 and the bit line 310 are formed, and a peripheral portion P excluding the central portion C.

The eighth insulating interlayer 770 may be formed on the peripheral portion P of the third substrate 30.

The second capacitor structure 750 may include a fifth capacitor electrode 740, a second dielectric layer 730, a fourth capacitor electrode 720 and a sixth mold 710 sequentially stacked in the third direction D3 on the third substrate 30.

The fifth capacitor electrode 740 may include a sixth portion covering an upper surface of the central portion C of the third substrate 30 and a sidewall and an upper surface of the eighth insulating interlayer 770, and a fifth portion protruding in the third direction D3 from the sixth portion on the central portion C.

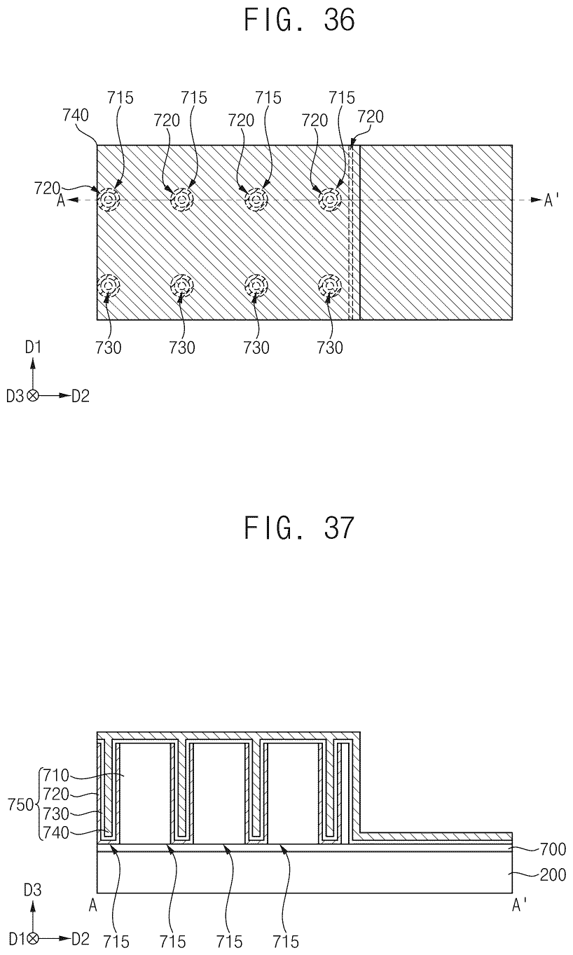

Referring to FIGS. 35 and 36 together with FIG. 29, in a plan view, the fifth portion of the fifth capacitor electrode 740 may have a shape of a circle, however, the present invention is not limited thereto. That is, in a plan view, the fifth portion of the fifth capacitor electrode 740 may have a shape of, for example, an oval, a rectangle, a square with rounded corners, etc. In addition, in a plan view, the fifth portion of the fifth capacitor electrode 740 may be arranged in a lattice pattern, but the present invention is not limited thereto. That is, in a plan view, the fifth portion of the fifth capacitor electrode 740 may be arranged in, for example, a honeycomb pattern.

The second dielectric layer 730 may be formed on the fifth capacitor electrode 740.

The fourth capacitor electrode 720 may be formed on a portion of the second dielectric layer 730 on the sixth portion of the fifth capacitor electrode 740. Accordingly, the fourth capacitor electrode 720 may have a shape of a reversed cup. A plurality of fourth capacitor electrodes 720 may be spaced apart from each other in the first and second directions D1 and D2 corresponding to the fifth capacitor electrode 740.

The sixth mold 710 may be formed between the fourth capacitor electrodes 720 to cover an upper surface of the second dielectric layer 730 and sidewalls of the fourth capacitor electrodes 720.

The mold structure 800 may extend in the first direction D1 on the central portion C of the third substrate 30, and a plurality of mold structures 800 may be spaced apart from each other in the second direction D2.

In example embodiments, the mold structure 800 may include a fifth mold 700 and a seventh mold 790 sequentially stacked in the third direction D3. The fifth mold 700 may have a third width in the second direction D2, and the seventh mold 790 may have a fourth width in the second direction D2 that is smaller than the third width. Accordingly, a cross-section in the second direction D2 of the mold structure 800 may have a shape of a reversed (i.e., upside-down) “T”.

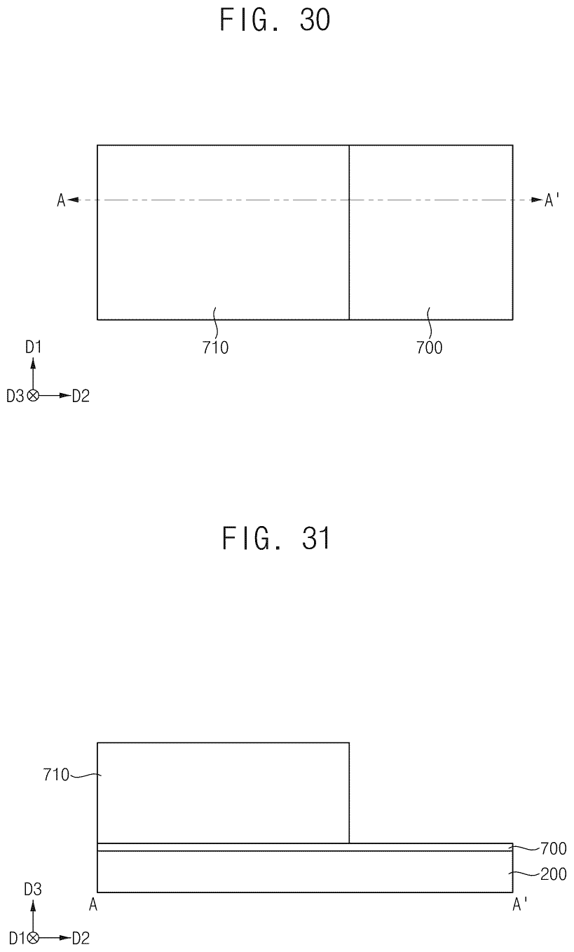

FIGS. 30 to 39 are plan views and cross-sectional views illustrating a method of manufacturing a semiconductor device according to example embodiments. Specifically, FIGS. 30, 32, 34, 36 and 38 are the plan views and FIGS. 31, 33, 35, 37 and 39 are cross-sectional views taken along lines A-A′, respectively, of corresponding plan views. This method may include processes substantially the same as or similar to those illustrated with reference to FIGS. 14 to 25, and thus repeated explanations thereof are omitted herein.

Referring to FIGS. 30 and 31, a fifth mold 700 and a sixth mold 710 may be sequentially formed on the first substrate 10. In example embodiments, the sixth mold 710 may be formed on the central portion C of the first substrate 10.

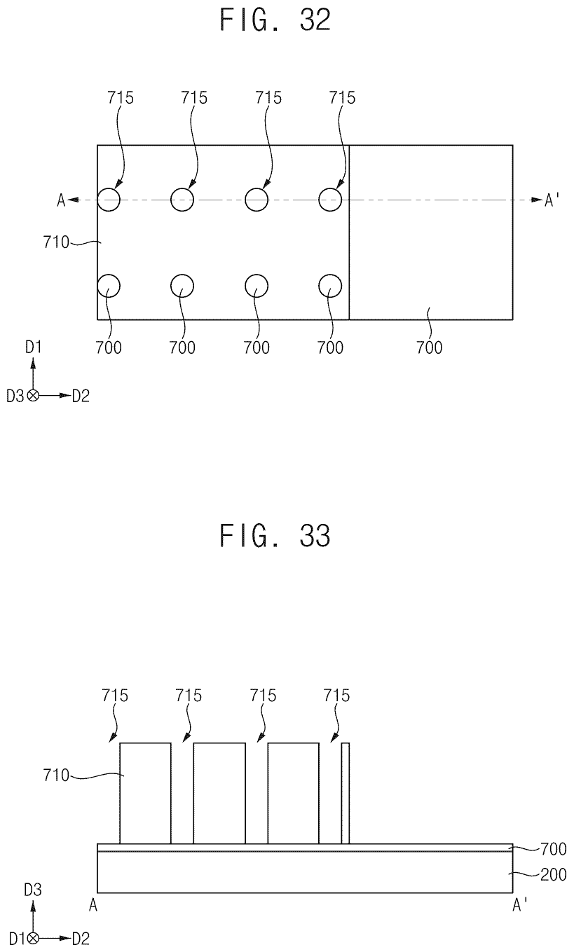

Referring to FIGS. 32 and 33, a portion of the sixth mold 710 may be etched to form a fifth opening 715 exposing an upper surface of the fifth mold 700.

In example embodiments, a plurality of fifth openings 715 may be spaced apart from each other in the first and second directions D1 and D2 to form a fifth opening array on the central portion C of the first substrate 10. The fifth opening array may include a plurality of fifth opening columns spaced apart from each other in the second direction D2. Each of the fifth opening columns may include the fifth openings 715 that are arranged in the first direction D1.

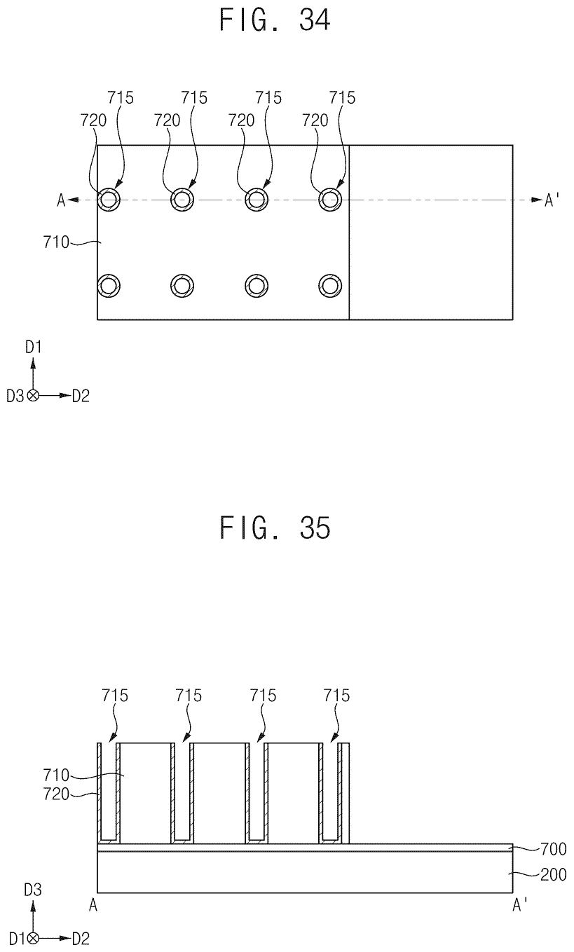

Referring to FIGS. 34 and 35, a fourth capacitor electrode 720 may be formed to cover a bottom and a sidewall of the fifth opening 715. Accordingly, the fourth capacitor electrode 720 may have a shape of, for example, a cup.

In example embodiments, a plurality of fourth capacitor electrodes 720 may be spaced apart from each other along each of the first and second directions D1 and D2 on the central portion C of the first substrate 10 to form a fourth capacitor electrode array. The fourth capacitor electrode array may include a plurality of fourth capacitor electrode columns spaced apart from each other in the second direction D2. Each of the fourth capacitor electrode columns may include the fourth capacitor electrodes 720 that are arranged in the first direction D1.

Referring to FIGS. 36 and 37, a second dielectric layer 730 and a fifth capacitor electrode 740 may be sequentially formed on the fourth capacitor electrode 720 and the fifth and sixth molds 700 and 710. The fifth capacitor electrode 740 may be formed in (e.g., to fill) the fifth opening 715 to a sufficient height. Accordingly, a portion of the fifth capacitor electrode 740 within the fifth opening 715 (hereinafter, referred to as a fifth portion) may have a shape of a pillar (e.g., a cylinder or rectangle), and a portion of the fifth capacitor electrode 740 outside the fifth opening 715 (hereinafter, referred to as a sixth portion) may cover upper surfaces of the second dielectric layer 730 and the fifth portion of the fifth capacitor electrode 740.

The sixth mold 710, the fourth capacitor electrode 720, the second dielectric layer 730 and the fifth capacitor electrode 740 may together form a second capacitor structure 750.

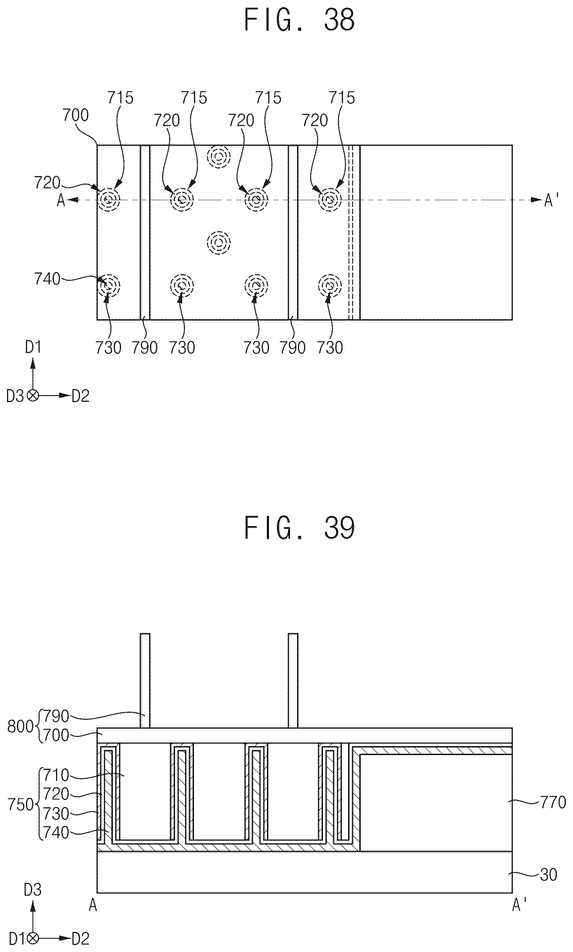

Referring to FIGS. 38 and 39, an eighth insulating interlayer 770 may be formed on the second capacitor structure 750, and a planarization process may be performed on an upper portion of the eighth insulating interlayer 770 until the upper surface of the sixth portion of the fifth capacitor electrode 740 is exposed.

For example, the planarization process may include a chemical mechanical polishing (CMP) process and/or an etch back process.

A third substrate 30 may be formed on the second capacitor structure 750 and the eighth insulating interlayer 770, and the cell array region I including the third substrate 30 may be turned over. Then, the first substrate 10 can be removed. Accordingly, an upper surface of the fifth mold 700 may be exposed. Hereinafter, the description will be made based on the state in which the various structures formed on the first substrate 10 are upside down. Hereinafter, the following description may be based on a state in which top and bottom of the structures on the first substrate 10 are inverted.

A seventh mold 790 may be formed on the exposed upper surface of the fifth mold 700. The seventh mold 790 may extend in the first direction D1 between neighboring ones of the fourth capacitor electrode columns in the second direction D2, and a plurality of seventh molds may be spaced apart from each other in the second direction D2.

Processes substantially the same as or similar to those illustrated with reference to FIGS. 14 to 25 may be performed to complete the fabrication of the semiconductor device.

The second capacitor structure 750 of the cell array region I illustrated with reference to FIG. 29 may be applied to the semiconductor device illustrated with reference to FIGS. 26 to 28.

While example embodiments have been particularly shown and described, it will be understood by one of ordinary skill in the art that variations in form and detail may be made therein without departing from the scope of the claims.

1. A semiconductor device comprising:
a cell array region, a bonding region and a central circuit region that are sequentially stacked, and a peripheral circuit region surrounding the cell array region, the cell array region including:
a capacitor structure, the capacitor structure including:
a capacitor electrode structure having a first capacitor electrode on an upper surface of a first substrate, a mold on the first capacitor electrode, the mold comprising an opening therein, and a second capacitor electrode on the upper surface of the first capacitor electrode and a surface of the mold;
a dielectric layer on a surface of the second capacitor electrode; and
a third capacitor electrode on the dielectric layer in the opening of the mold;
a first gate structure on the capacitor structure;
a channel on the third capacitor electrode, the channel having a semiconductor material with a first band gap energy greater than a second band gap energy of polysilicon; and
a bit line on the first gate structure and the channel,
wherein the central circuit region includes a transistor on a second substrate, the transistor including a second gate structure and a source/drain region,
wherein the bonding region includes a bonding structure that bonds the cell array region and the central circuit region to each other, and
wherein the peripheral circuit region includes a peripheral circuit pattern that is configured to apply electrical signals to the cell array region.

2. The semiconductor device of claim 1, wherein the bonding structure includes silicon carbonitride (SiCN).

3. The semiconductor device of claim 1, further comprising a wiring region on the central circuit region,
wherein the cell array region further includes first contact plugs electrically connected to the capacitor structure, the first gate structure, and the bit line, respectively,
wherein the central circuit region further includes a second contact plug electrically connected to the transistor, and
wherein the wiring region includes a third contact plug electrically connecting the cell array region and the peripheral circuit region or the central circuit region and the peripheral circuit region.

4. The semiconductor device of claim 3,
wherein the bonding structure includes a first bonding layer on an upper surface of the cell array region and a second bonding layer on a lower surface of the central circuit region, and
wherein the first bonding layer and the second bonding layer directly contact each other.

5. The semiconductor device of claim 4,
wherein a width in a first direction of each of the first contact plugs, the second contact plug, and the third contact plug increases in a vertical direction away from the upper surface of the first substrate,
wherein the first direction is substantially parallel to the upper surface of the first substrate, and
wherein the vertical direction is substantially perpendicular to the upper surface of the first substrate.

6. The semiconductor device of claim 3,
wherein the bonding structure includes a first bonding layer that directly contacts the cell array region and a second bonding layer that directly contacts the central circuit region, and
wherein the first bonding layer and the second bonding layer directly contact each other.

7. The semiconductor device of claim 6,
wherein a width in a first direction of each of the first contact plugs and the third contact plug increases in a vertical direction away from the upper surface of the first substrate,
wherein a width in the first direction of the second contact plug decreases in the vertical direction away from the upper surface of the first substrate,
wherein the first direction is substantially parallel to the upper surface of the first substrate, and
wherein the vertical direction is substantially perpendicular to the upper surface of the first substrate.

8. The semiconductor device of claim 3, wherein the bonding structure includes:
a first bonding structure having:
a first bonding layer on an upper surface of the cell array region; and
a first bonding contact and a first bonding pad sequentially stacked in a vertical direction, the first bonding contact and the first bonding pad extending in the first bonding layer, the vertical direction substantially perpendicular to the upper surface of the first substrate, and
a second bonding structure having:
a second bonding layer on a lower surface of the central circuit region; and
a second bonding pad and a second bonding contact sequentially stacked in the vertical direction on the first bonding pad, the second bonding pad and the second bonding contact extending in the second bonding layer.

9. The semiconductor device of claim 8,
wherein a width in a first direction of each of the first contact plugs, the second contact plug, the third contact plug, and the first bonding contact increase in the vertical direction away from the upper surface of the first substrate,
wherein a width in the first direction of the second bonding contact decreases in the vertical direction away from the upper surface of the first substrate, and
wherein the first direction is substantially parallel to the upper surface of the first substrate.

10. The semiconductor device of claim 9, wherein the second bonding contact extends through the second substrate.

11. The semiconductor device of claim 3, wherein the bonding structure includes:
a first bonding structure having:
a first bonding layer on an upper surface of the cell array region; and
a first bonding contact and a first bonding pad sequentially stacked in a vertical direction, the first bonding contact and the first bonding pad extending in the first bonding layer, the vertical direction substantially perpendicular to the upper surface of the first substrate, and
a second bonding structure having:
a second bonding layer between the first bonding layer and the central circuit region; and
a second bonding pad and a second bonding contact sequentially stacked in the vertical direction on the first bonding pad, the second bonding pad and the second bonding contact extending in the second bonding layer.

12. The semiconductor device of claim 11,
wherein a width in a first direction of each of the first contact plugs, the second contact plug, the third contact plug, and the first bonding contact increase in the vertical direction away from the upper surface of the first substrate,
wherein a width in the first direction of each of the second contact plug and the second bonding contact decreases in the vertical direction away from the upper surface of the first substrate, and
wherein the first direction is substantially parallel to the upper surface of the first substrate.

13-20. (canceled)

21. A semiconductor device comprising:
a cell array region;
a central circuit region that is on top of the cell array region; and
a bonding region that is between the cell array region and the central circuit region and that bonds the cell array region and the central circuit region to each other, wherein the cell array region includes:
a capacitor structure;
a first gate structure on the capacitor structure;
a channel on the first gate structure; and
a bit line on the first gate structure and the channel,
wherein the central circuit region includes a transistor including a second gate structure and a source/drain region.

22. The semiconductor device of claim 21, further comprising a wiring region on the central circuit region,
wherein the wiring region includes a contact plug that extends into the central circuit region.

23. The semiconductor device of claim 22, wherein the contact plug of the wiring region overlaps the capacitor structure of the cell array region in a vertical direction.

24. The semiconductor device of claim 23,
wherein the capacitor structure comprises a first capacitor electrode, a second capacitor electrode, and a third capacitor electrode,
wherein the second capacitor electrode is between the first capacitor electrode and the third capacitor electrode,
wherein the contact plug of the wiring region overlaps the first capacitor electrode and the second capacitor electrode in the vertical direction, and
wherein the contact plug of the wiring region does not overlap the third capacitor electrode in the vertical direction.

25. The semiconductor device of claim 24,
wherein the capacitor structure further comprises a mold and a dielectric layer,
wherein the mold is on the first capacitor electrode, the mold comprising an opening therein,
wherein the second capacitor electrode is on an upper surface of the first capacitor electrode and a surface of the mold,
wherein the dielectric layer is on the second capacitor electrode, and
wherein the third capacitor electrode is on the dielectric layer in the opening of the mold.

26. The semiconductor device of claim 22, wherein the contact plug of the wiring region does not overlap, in a vertical direction, the first gate structure, the channel, or the bit line.

27. A semiconductor device comprising:
a cell array region;
a central circuit region that is on top of the cell array region, wherein the central circuit region includes a transistor;
a back-end-of-line (BEOL) region on the central circuit region, wherein the BEOL region includes a contact plug that extends into the central circuit region; and
a bonding region that is between the cell array region and the central circuit region and that bonds the cell array region and the central circuit region to each other, wherein the cell array region includes:
a capacitor structure;
a first gate structure on the capacitor structure;
a channel on the first gate structure; and
a bit line on the first gate structure and the channel,
wherein the central circuit region includes a transistor including a second gate structure and a source/drain region.

28. The semiconductor device of claim 27, wherein the capacitor structure comprises:
a capacitor electrode structure having a first capacitor electrode on an upper surface of a first substrate, a mold on the first capacitor electrode, the mold comprising an opening therein, and a second capacitor electrode on an upper surface of the first capacitor electrode and a surface of the mold;
a dielectric layer on a surface of the second capacitor electrode; and
a third capacitor electrode on the dielectric layer in the opening of the mold.
